(19) United States
(12) Patent Application Publication
(10) Pub. No.: US 2022/0216084 A1
(43) Pub. Date: Jul. 7, 2022

(54) METHOD FOR TRANSFERRING ELECTRONIC COMPONENT

(71) Applicant: ASTI GLOBAL INC., TAIWAN, Taichung City (TW)

(72) Inventor: CHING-JU LIN, Taichung City (TW)

(21) Appl. No.: 17/533,134

(22) Filed: Nov. 23, 2021

(30) Foreign Application Priority Data
Jan. 7, 2021 (TW) 110100614

(51) Int. Cl. H01L 21/677

(52) U.S. Cl. CPC H01L 21/67742; H01L 2933/0033

(57) ABSTRACT

A method for transferring electronic components. First, a transfer substrate is provided, which has a surface on which a plurality of cavities are formed, such that the carrier substrate to face the surface of the transfer substrate in a manner that a portion of the electronic components are arranged corresponding to at least a portion of the plurality of cavities on the transfer substrate, and then releasing and allowing the portion of electronic components that are arranged corresponding to the at least a portion of the plurality of cavities to fall into the cavities.

### CROSS-REFERENCE TO RELATED APPLICATION

This non-provisional application claims priority under 35 U.S.C. § 119(a) on Patent Application No(s). 110100614 filed in Taiwan, R.O.C. on Jan. 7, 2021, the entire contents of which are hereby incorporated by reference.

### BACKGROUND OF THE INVENTION

### 1. Field of the Invention

The present disclosure relates to transfer methods, and in particular to a method for transferring electronic components.

### 2. Description of the Related Art

Electronic devices nowadays have increasingly complicated functions, and the required numbers of their electronic components are on the rise, thanks to ever-changing technology and ever-increasing consumer needs. Ongoing trend toward miniaturization of electronic components is required to downsize electronic devices and enhance their performance.

For instance, light emitting diode (LED) display devices are one of the topics of research carried out on display units. However, to meet the requirement for high resolution, LED display devices are trending toward microscale LEDs arranged in an array and the resultant tremendous need of transfer.

Therefore, it is important to provide a method for transferring electronic components rapidly and precisely.

### BRIEF SUMMARY OF THE INVENTION

An objective of the present disclosure is to provide a method for transferring electronic components, allowing the carrier substrate to face a surface of the transfer substrate in a manner that a portion of the electronic components are arranged corresponding to at least a portion of a plurality of cavities on the transfer substrate, and releasing and allowing the portion of electronic components that are arranged corresponding to the at least a portion of the plurality of cavities to fall into the cavities. The transfer substrate has a surface on which the plurality of cavities are formed. The cavities ensure that the electronic components fall into correct positions when released. Therefore, the method is effective in transferring electronic components rapidly and precisely.

Therefore, according to the present disclosure, a method for transferring electronic components is provided, such that the electronic components that are not arranged corresponding to the at least a portion of the plurality of cavities come into contact with the surface of the transfer substrate on which the plurality of cavities are not formed, and releasing and allowing the portion of electronic components that are arranged corresponding to the at least a portion of the plurality of cavities to fall into the cavities, thereby shortening the distance which separates the released electronic components from the transfer substrate. The transfer substrate has cavities for receiving electronic components of the carrier substrate. The cavities ensure that the electronic components fall into correct positions when released. Therefore, the method is effective in transferring electronic components rapidly and precisely and achieving satisfactory production yield.

### BRIEF DESCRIPTION OF THE DRAWINGS

FIG. 1A through FIG. 1D are schematic views of a process flow of a method for transferring electronic components according to an embodiment of the present disclosure.

FIG. 2A through FIG. 2F are schematic views of a process flow of a method for transferring LED chips according to an embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

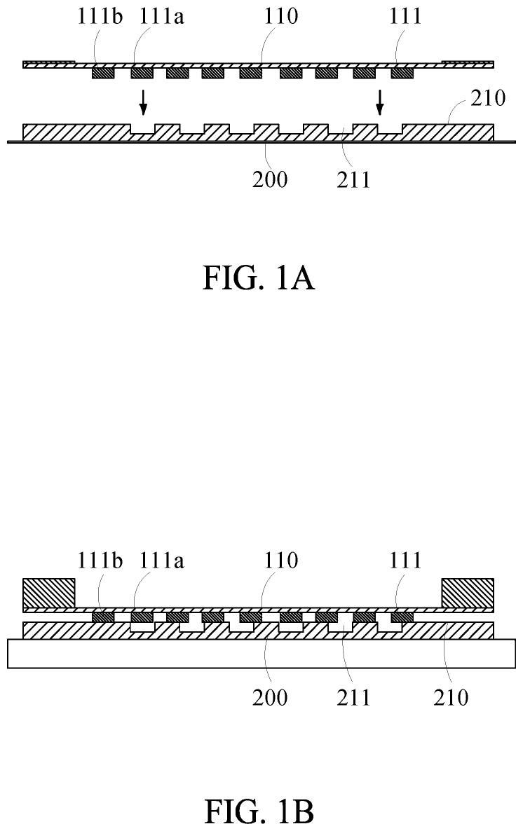

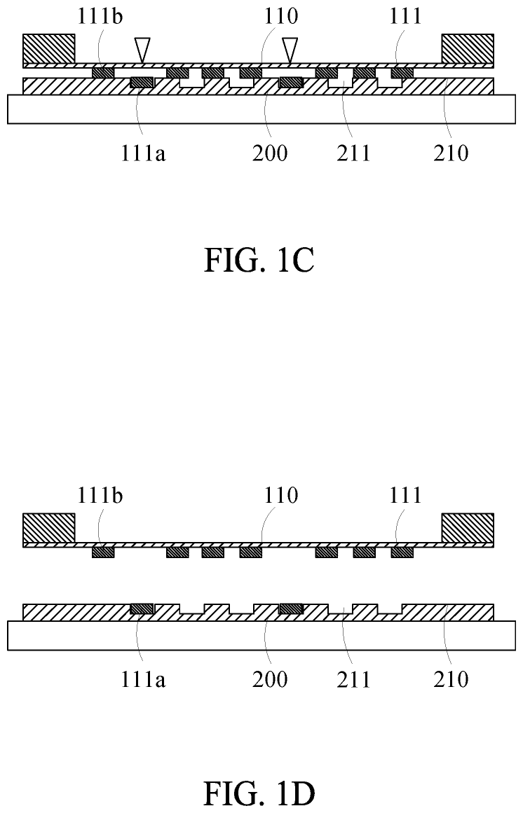

FIG. 1A through FIG. 1D are schematic views of a process flow of a method for transferring electronic components according to an embodiment of the present disclosure. Referring to FIG. 1A, a carrier substrate 110 and a transfer substrate 200 are provided. The carrier substrate 110 carries a plurality of electronic components 111. The transfer substrate 200 has a surface 210 on which a plurality of cavities 211 are formed. The carrier substrate 110 is, for example, an adhesive film or a substrate with an adhesive film, and is adapted to adhere to and carry the plurality of electronic components 111. The adhesive film is, for example, made of polyimide, but the present disclosure is not limited thereto. The transfer substrate 200 is a transparent substrate, for example, glass substrate, quartz substrate or sapphire substrate, but the present disclosure is not limited thereto. The plurality of electronic components 111 carried by the carrier substrate 110 have identical dimensions. The dimensions of the electronic components 111 are equal to or greater than 100 μm. The electronic components 111 are, for example, integrated circuit chips, but the present disclosure is not limited thereto. The dimensions of the electronic components 111 are not greater than 100 μm. The electronic components 111 are, for example, LED chips, for example, Mini LED chips or Micro LED chips, but the present disclosure is not limited thereto. The depth of the plurality of cavities is equal to or less than the height of the electronic components 111. The plurality of cavities 211 are formed on the surface 210 of the transfer substrate 200 by a laser ablation or a chemical etching, but the present disclosure is not limited thereto. The laser for use in the laser ablation is, for example, visible light or invisible light. The chemical etching is, for example, dry etching or wet etching, but the present disclosure is not limited thereto.

Referring to FIG. 1A, the plurality of electronic components 111 on the carrier substrate 110 face the surface 210 of the transfer substrate 200 in a manner that a portion of the electronic components 111 (for example, electronic components 111a) are arranged corresponding to at least a portion of the plurality of cavities 221 on the transfer substrate 200 but the other electronic components 111 (for example, electronic components 111b) not to align with the cavities 211 on the transfer substrate 200, by image-based positioning, but the present disclosure is not limited thereto.

Referring to FIG. 1B, the relative position of the carrier substrate 110 to the transfer substrate 200 are changed till the electronic components 111 that are not arranged corresponding to the at least a portion of the plurality of cavities 211 come into contact with the surface 210 of the transfer substrate 200 on which the plurality of cavities 211 are not formed, for example, by moving one of the carrier substrate 100 and the transfer substrate 200 toward the other, and the electronic components 111 (for example, electronic components 111b) not aligned with the cavities 211 come into contact with a cavity-free part (i.e., a part free of the cavities 211) of the surface 210 of the transfer substrate 200. A force sensing or an optical distance sensing determines whether the electronic components 111 not aligned with the cavities 211 are in contact with a cavity-free part (i.e., a part free of the cavities 211) of the surface 210 of the transfer substrate 200.

Referring to FIG. 1C, the electronic components 111 (for example, electronic components 111a) that are arranged corresponding to the at least a portion of the plurality of cavities 211 are released and allowed to fall into the cavities. The release process is started by transferring energy to, for example, the electronic components 111 aligned with the cavities 211, such that the adhesiveness of the adhesive layer of the carrier substrate 110 diminishes, thereby releasing the electronic components 111 from the carrier substrate 110. The energy transfer is carried out by emitting a laser beam or ultrasonic waves toward the adhesive layers of the electronic components 111 aligned with the cavities 211, as shown in FIG. 1C, but the present disclosure is not limited thereto.

Referring to FIG. 1D, the relative position of the carrier substrate 110 to the transfer substrate 200 is changed to draw the two substrates away from each other, such that one of the carrier substrate 100 and transfer substrate 200 moves away from the other, and the electronic components 111 aligned with the cavities 211 are not in contact with a cavity-free part (i.e., a part free of the cavities 211) of the surface 210 of the transfer substrate 200. In this embodiment, the electronic components 111 disposed on the carrier substrate 100 but not aligned with the cavities 211 are further used in the next instance of transfer.

In this embodiment, the method for transferring the present disclosure enables the electronic components 111 disposed on the carrier substrate 110 but not aligned with the cavities 211 to come into contact with a cavity-free part (i.e., a part free of the cavities 211) of the surface 210 of the transfer substrate 200, and then allows the electronic components 111 aligned with the cavities 211 to be released, such that the distance between the electronic components 111 on the carrier substrate 110 and the surface 210 of the transfer substrate 200 is capped by the height of the electronic components 111, so as to reduce the distance which separates the electronic components 111 from the transfer substrate 200 and lower the chance that the electronic components 111 will, in the course of its fall, drift or separate from the transfer substrate 200. The transfer substrate 200 has the cavities 211 for receiving the electronic components 111 of the carrier substrate 110. When released, the electronic components 111 are guided by the cavities 211 to their correct positions. Therefore, the method for transferring electronic components of the present disclosure enhances production yield.

The method for transferring LED chips is described above step by step and below generally.

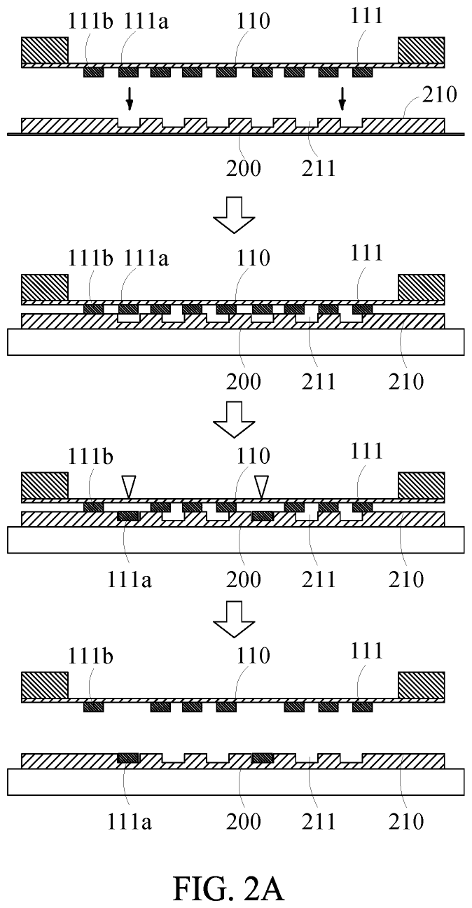

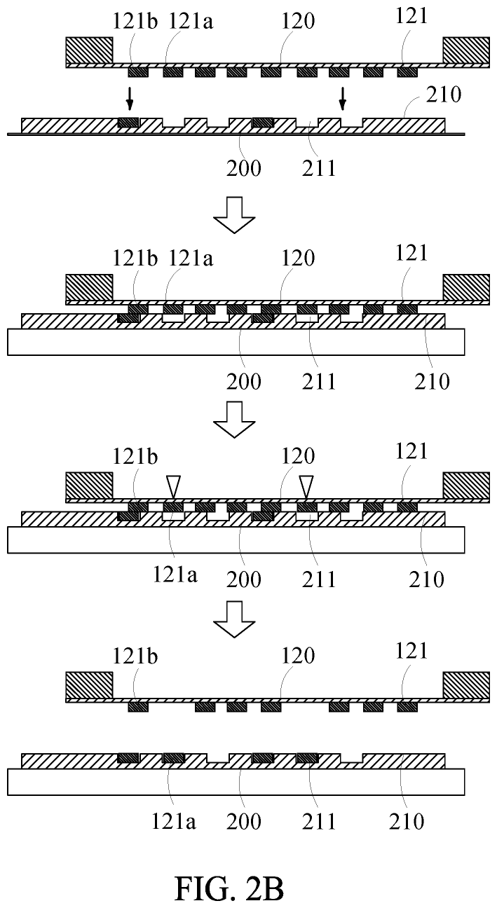

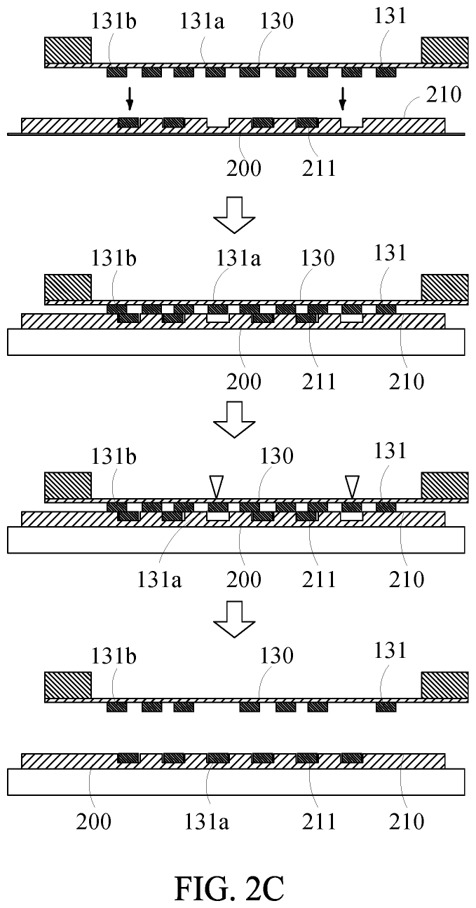

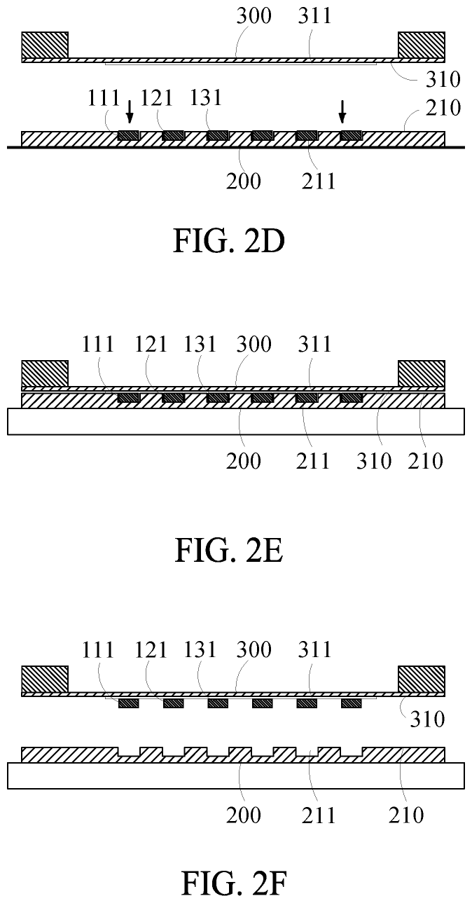

Referring to FIG. 2A, the method for transferring electronic components illustrated with FIG. lA through FIG. 1D provides a carrier substrate 110 and a transfer substrate 200. The plurality of electronic components 111 on the carrier substrate 110 face the surface 210 of the transfer substrate 200. The plurality of cavities 211 are disposed on the surface 210. A portion of the electronic components 111 are aligned with the plurality of cavities 211 on the transfer substrate 200. Then, the relative position of the carrier substrate 110 to the transfer substrate 200 is changed, and the electronic components 111 not aligned with the cavities 211 come into contact with a cavity-free part (i.e., a part free of the cavities 211) of the surface 210 of the transfer substrate 200. Then, the electronic components 111 disposed on the carrier substrate 110 and aligned with the cavities 211 are released to the cavities 211. The electronic components 111 are LED chips which emit red (R) light.

Referring to FIG. 2B, the method for transferring electronic components illustrated with FIG. 1A through FIG. 1D provides a carrier substrate 120. The plurality of electronic components 121 on the carrier substrate 120 face the surface 210 of the transfer substrate 200. The plurality of cavities 211 are disposed on the surface 210. A portion of the electronic components 121 (for example, electronic components 121a) are aligned with the cavities 211 disposed on the transfer substrate 200 but not receiving the electronic components 111. Then, the relative position of the carrier substrate 120 to the transfer substrate 200 is changed, and the electronic components 121 (for example, electronic components 121b) not aligned with the cavities 211 come into contact with a cavity-free part (i.e., a part free of the cavities 211) of the surface 210 of the transfer substrate 200. Then, the electronic components 111 disposed on the carrier substrate 120 and aligned with the cavities 211 are released to the cavities 211. The electronic components 121 are LED chips which emit green (G) light.

Referring to FIG. 2C, the method for transferring electronic components illustrated with FIG. 1A through FIG. 1D provides a carrier substrate 130. The plurality of electronic components 131 on the carrier substrate 130 face the surface 210 of the transfer substrate 200. The plurality of cavities 211 are disposed on the surface 210. A portion of the electronic components 131 (for example, electronic components 131a) are aligned with the cavities 211 disposed on the transfer substrate 200 but not receiving the electronic components 111 or electronic components 121. Then, the relative position of the carrier substrate 130 to the transfer substrate 200 is changed, and the electronic components 131 (for example, electronic components 131b) not aligned with the cavities 211 come into contact with a cavity-free part (i.e., a part free of the cavities 211) of the surface 210 of the transfer substrate 200. Then, the electronic components 131 disposed on the carrier substrate 130 and aligned with the cavities 211 are released to the cavities 211. The electronic components 131 are LED chips which emit blue (B) light. Therefore, the cavities 211 of the transfer substrate 200 each receive one of the electronic component 111, electronic component 121 and electronic component 131. The electronic components 111, electronic components 121 and electronic components 131 are arranged in a pixel array in the plurality of cavities 211 of the transfer substrate 200.

Referring to FIG. 2D, a carrier substrate 300 is provided. The carrier substrate 300 has a surface 310 with an adhesive film 311 thereon.

Referring to FIG. 2E, the surface 310 of the carrier substrate 300 faces the surface 210 of the transfer substrate 200. The plurality of cavities 211 are disposed on the surface 210. The relative position of the carrier substrate 300 to the transfer substrate 200 is changed. The adhesive film 311 of the carrier substrate 300 comes into contact with and thus adheres to the electronic components 111, 121, 131 in the plurality of cavities 211 of the transfer substrate 200.

Referring to FIG. 2F, the relative position of the carrier substrate 300 to the transfer substrate 200 is changed to draw the two substrates away from each other, such that the electronic components 111, 121 or 131 received in the cavities 211 are adhered to the surface 310 of the carrier substrate 300 and leave the cavities 211 and thus are transferred to the carrier substrate 300.

In this embodiment, the pixel array formed on the transfer substrate 200 depends on the pixel array of the circuit substrate of a display device. Therefore, the electronic components 111, 121, 131 transferred to the carrier substrate 300 and pixel array thus formed can be transferred to the circuit substrate of the display device in one single instance of a transfer process. Therefore, the method for transferring electronic components of the present disclosure is effective in transferring a large number of pixels on the circuit substrate rapidly and precisely, reducing the transfer cost incurred in a display device manufacturing process, and achieving satisfactory production yield.

In conclusion, the method for transferring electronic components of the present disclosure enables electronic components disposed on a carrier substrate but not aligned with cavities therein to come into contact with a cavity-free part of a surface of a transfer substrate and then allows the electronic components aligned with the cavities to be released, so as to shorten the distance which separates the electronic components of the carrier substrate from the surface of the transfer substrate and lower the chance that the electronic components will, in the course of its fall, drift or separate from the transfer substrate. Furthermore, the transfer substrate has cavities for receiving the electronic components of the carrier substrate, such that the released electronic components are guided by the cavities to their correct positions. Therefore, the method for transferring electronic components of the present invention has satisfactory production yield.

While the present disclosure has been described by means of specific embodiments, numerous modifications and variations could be made thereto by those skilled in the art without departing from the scope and spirit of the present disclosure set forth in the claims.

What is claimed is:

1. A method for transferring electronic components, comprising the steps of:
providing a carrier substrate and a transfer substrate, wherein the carrier substrate carries a plurality of electronic components and the transfer substrate has a surface on which a plurality of cavities are formed;
allowing the carrier substrate to face the surface of the transfer substrate in a manner that a portion of the electronic components are arranged corresponding to at least a portion of the plurality of cavities on the transfer substrate;
changing the relative position of the carrier substrate to the transfer substrate till the electronic components that are not arranged corresponding to the at least a portion of the plurality of cavities come into contact with the surface of the transfer substrate on which the plurality of cavities are not formed; and
releasing and allowing the portion of electronic components that are arranged corresponding to the at least a portion of the plurality of cavities to fall into the cavities.

2. The method for transferring electronic components according to claim 1, wherein the depth of the plurality of cavities is equal to or less than the height of the electronic components.

3. The method for transferring electronic components according to claim 1, wherein the step of releasing and allowing the portion of electronic components that are arranged corresponding to the at least a portion of the plurality of cavities to fall into the cavities is performed with a laser beam or an ultrasonic wave.

4. The method for transferring electronic components according to claim 1, wherein the step of allowing the carrier substrate to face the surface of the transfer substrate in a manner that a portion of the electronic components are arranged corresponding to at least a portion of the plurality of cavities on the transfer substrate is performed by image-based positioning.

5. The method for transferring electronic components according to claim 1, wherein the step of changing the relative position of the carrier substrate to the transfer substrate till the electronic components that are not arranged corresponding to the at least a portion of the plurality of cavities come into contact with the surface of the transfer substrate on which the plurality of cavities are not formed is performed by determining, with a force sensing or an optical distance sensing, whether the electronic components not aligned with the cavities are in contact with a cavity-free part of the surface of the transfer substrate.

6. The method for transferring electronic components according to claim 1, wherein the carrier substrate is a transparent substrate.

7. The method for transferring electronic components according to claim 1, wherein the electronic components are LED chips.

8. The method for transferring electronic components according to claim 7, wherein dimensions of the LED chips are greater than or equal to 100 μm.

9. The method for transferring electronic components according to claim 7, wherein dimensions of the LED chips are less than 100 μm.

10. The method for transferring electronic components according to claim 1, wherein the electronic components are integrated circuit chips.

11. The method for transferring electronic components according to claim 1, wherein the plurality of cavities are formed on the surface of the transfer substrate by a laser ablation or a chemical etching.
